(19) United States
(12) Patent Application Publication
(10) Pub. No.: US 2024/0371717 A1
(43) Pub. Date: Nov. 7, 2024

(54) SEMICONDUCTOR DEVICE

(71) Applicant: SAMSUNG ELECTRONICS CO., LTD., Suwon-si (KR)

(72) Inventors: Donggon Yoo, Suwon-si (KR); Sunjung Lee, Suwon-si (KR); Jeongwon Hwang, Suwon-si (KR); Myung-Ho Kong, Suwon-si (KR); Yongho Ha, Suwon-si (KR)

(21) Appl. No.: 18/409,221

(22) Filed: Jan. 10, 2024

(30) Foreign Application Priority Data
May 3, 2023 (KR) 10-2023-0057807

(51) Int. Cl. H01L 23/31; H01L 23/29; H01L 23/528; H01L 23/532

(52) U.S. Cl. CPC H01L 23/3178; H01L 23/291; H01L 23/5283; H01L 23/53266

(57) ABSTRACT

A semiconductor device includes a mold layer defining a trench and a conductive structure disposed on the trench. The conductive structure includes a conductive layer and a liner, and the conductive layer includes upper and lower portions. The liner includes a base portion and a sidewall portion on the base portion, and the upper portion of the conductive layer is disposed at a level higher than the sidewall portion of the liner. The sidewall portion of the liner is interposed between the lower portion of the conductive layer and the mold layer, and a top surface of the base portion of the liner is in contact with a bottom surface of the lower portion of the conductive layer. A width of the sidewall portion of the liner may decrease as a level increases.

### CROSS-REFERENCE TO RELATED APPLICATIONS

This U.S. non-provisional patent application claims priority under 35 U.S.C. § 119 to Korean Patent Application No. 10-2023-0057807, filed on May 3, 2023, in the Korean Intellectual Property Office, the entire contents of which are hereby incorporated by reference.

### BACKGROUND

The present disclosure relates to a semiconductor device, and in particular, to a semiconductor device including a conductive structure.

A semiconductor device includes an integrated circuit composed of metal-oxide-semiconductor field-effect transistors (MOS-FETs). To meet the increasing demand for semiconductor devices with a small pattern size, MOS-FET sizes are decreasing. The reduced scale of the MOS-FETs may lead to deterioration in operational properties of the semiconductor device. A variety of studies are being conducted to overcome technical limitations associated with the reduced scale of the semiconductor device and to realize high-performance semiconductor devices.

### SUMMARY

A liner interposed between a mold layer and a conductive layer of the semiconductor device can facilitate the stable formation of the conductive layer in which a seam is prevented from forming. Semiconductor devices using the presently disclosed processes are, in some implementations, less likely to experience melting and residue issues during chemical mechanical polishing (CMP), and therefore exhibit increased reliability.

In general, innovative aspects of the subject matter described in this specification can be embodied in a semiconductor device including: a mold layer defining a trench and a conductive structure disposed on the trench. The conductive structure may include a conductive layer and a liner, and the conductive layer may include upper and lower portions. The liner may include a base portion and a sidewall portion on the base portion, and the upper portion of the conductive layer may be disposed at a level higher than the sidewall portion of the liner. The sidewall portion of the liner may be interposed between the lower portion of the conductive layer and the mold layer, and a top surface of the base portion of the liner may be in contact with a bottom surface of the lower portion of the conductive layer. A width of the sidewall portion of the liner may decrease as a level increases.

Another general aspect can be embodied in a semiconductor device including: a mold layer defining a trench and a conductive structure disposed on the trench. The conductive structure may include a conductive layer and a liner, and the conductive layer may include upper and lower portions. The liner may include a base portion and a sidewall portion on the base portion, and the sidewall portion may be interposed between the lower portion of the conductive layer and the mold layer. The sidewall portion may include an inner sidewall in contact with the lower portion of the conductive layer and an outer sidewall in contact with the mold layer. An angle between the outer sidewall of the sidewall portion and a bottom surface of the base portion may be smaller than an angle between the inner sidewall of the sidewall portion and a top surface of the base portion.

Another general aspect can be embodied in a semiconductor device including: a mold layer defining a trench and a conductive structure disposed on the trench. The conductive structure may include a conductive layer and a liner, and the liner may be interposed between the mold layer and the conductive layer. The conductive layer and the liner may include molybdenum (Mo), and the liner may further include oxygen (O).

### BRIEF DESCRIPTION OF THE DRAWINGS

FIG. 1A is a sectional view illustrating an example of a semiconductor device.

FIG. 1B is an enlarged sectional view illustrating a portion ‘E’ of FIG. 1A.

FIGS. 2A, 2B, 2C, 2D, and 2E are sectional views illustrating an example of a method of fabricating the semiconductor device according to FIGS. 1A and 1B.

FIGS. 3, 4, 5, 6, 7, 8, 9A, and 9B are sectional views illustrating examples of semiconductor device.

### DETAILED DESCRIPTION

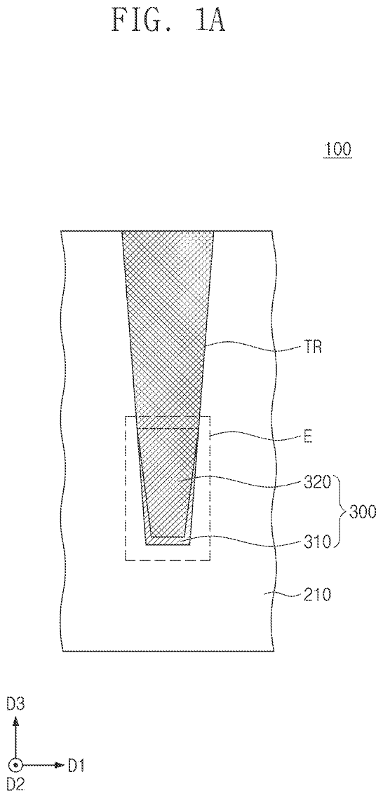

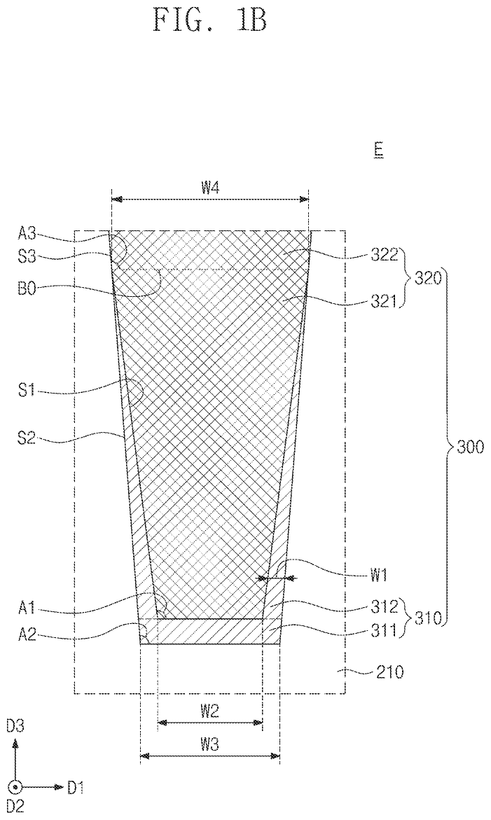

FIG. 1A is a sectional view illustrating an example of a semiconductor device 100. FIG. 1B is an enlarged sectional view illustrating a portion ‘E’ of FIG. 1A.

Referring to FIGS. 1A and 1B, a semiconductor device 100 includes a mold layer 210 and a conductive structure 300.

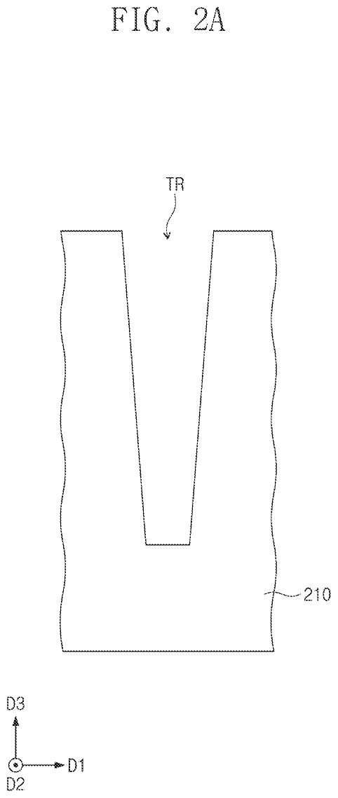

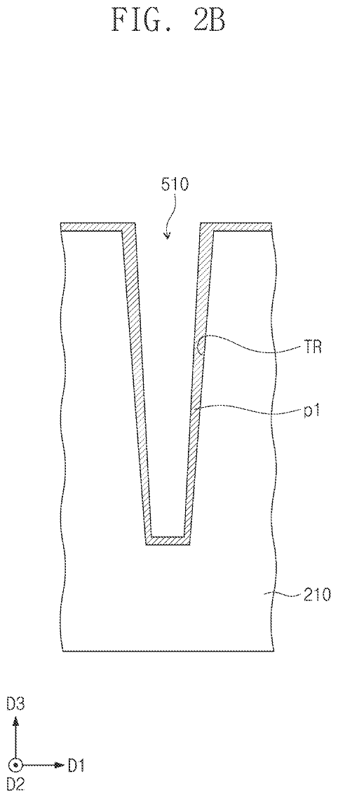

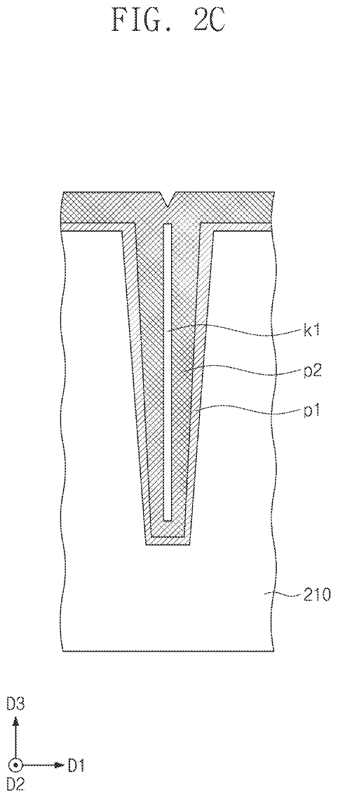

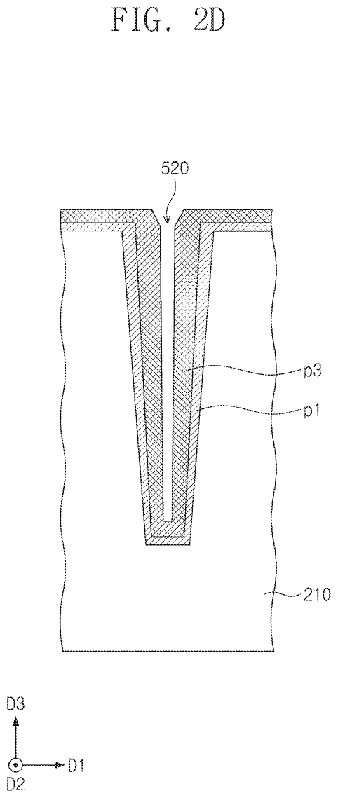

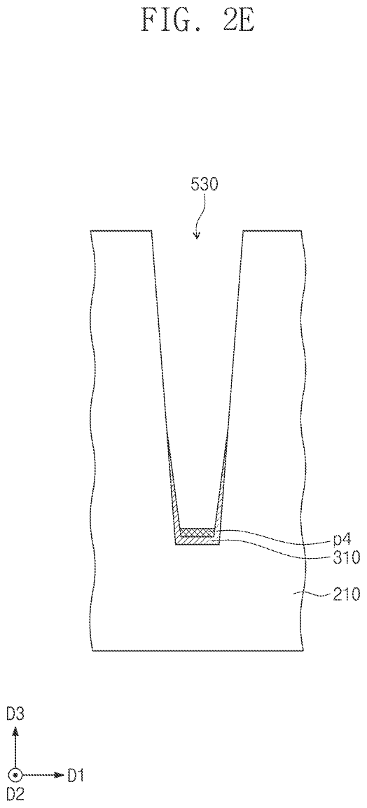

The mold layer 210 extends in a first direction D1 and a second direction D2. The first and second directions D1 and D2 may be non-parallel to each other. In some implementations, the first and second directions D1 and D2 are two different horizontal directions, which are orthogonal to each other. With reference to FIG. 2A, the mold layer 210 may be provided to have a trench TR. The conductive structure 300 may be provided in the trench TR of the mold layer 210. The mold layer 210 may include at least one of insulating materials. As an example, the mold layer 210 may be formed of or include at least one of oxide materials or nitride materials. In some implementations, the conductive structure 300 has a line shape extending in the second direction D2. In some implementations, the conductive structure 300 has a pillar shape enclosed by the mold layer 210.

The conductive structure 300 may be provided on the mold layer 210. A width of a top surface of the conductive structure 300 may be larger than a width of a bottom surface of the conductive structure 300. As an example, the conductive structure 300 may have a tapered shape, with the width decreasing as the vertical height decreases. A height of the conductive structure 300 may vary. As an example, a height of the conductive structure 300 in a third direction D3 may range from 100 nm to 1000 nm. The width of bottom surface of the conductive structure 300 may vary. As an example, the width of the bottom surface of the conductive structure 300 in the first direction D1 may be equal to or less than 20 nm. The conductive structure 300 may include a liner 310 and a conductive layer 320 on the liner 310. The liner 310 may include abase portion 311 and a sidewall portion 312 on the base portion 311. The conductive layer 320 may include a lower portion 321 and an upper portion 322.

The base portion 311 of the liner 310 may be provided on the mold layer 210. The sidewall portion 312 of the liner 310 may be interposed between the lower portion 321 of the conductive layer 320 and the mold layer 210. The sidewall portion 312 of the liner 310 may include an inner sidewall S1 and an outer sidewall S2. The inner sidewall S1 of the sidewall portion 312 may be in contact with the lower portion 321 of the conductive layer 320. The outer sidewall S2 of the sidewall portion 312 may be in contact with the mold layer 210. An interface BO may be defined between the lower and upper portions 321 and 322 of the conductive layer 320. The inner and outer sidewalls S1 and S2 of the sidewall portion 312 may meet each other at the same level as the interface BO. Here, the term ‘level’ may refer to a position in the third direction D3, e.g., a height.

The lower portion 321 of the conductive layer 320 may be provided on the liner 310. A bottom surface of the lower portion 321 of the conductive layer 320 may be in contact with a top surface of the base portion 311 of the liner 310. The lower portion 321 of the conductive layer 320 may be enclosed by the sidewall portion 312 of the liner 310. The lower portion 321 of the conductive layer 320 may be spaced apart from the mold layer 210 by the liner 310. The upper portion 322 of the conductive layer 320 may be placed at a level higher than the sidewall portion 312 of the liner 310. The lower portion 321 of the conductive layer 320 may be disposed at the same level as the sidewall portion 312 of the liner 310. The upper portion 322 of the conductive layer 320 may be enclosed by the mold layer 210. The upper portion 322 of the conductive layer 320 may include a sidewall S3 in contact with the mold layer 210.

The liner 310 and the conductive layer 320 may include at least one of conductive materials. The liner 310 and the conductive layer 320 may include at least one of metallic materials. As an example, the liner 310 may be formed of or include at least one of TiN, TaN, MoN, WN, TiSiN, TaSiN, MoSiN, WSiN, or Mo. As an example, the conductive layer 320 may be formed of or include molybdenum (Mo).

In some implementations, the liner 310 further contains oxygen (O), and the conductive layer 320 may not contain oxygen (O).

In some implementations, the liner 310 and the conductive layer 320 further contain oxygen (O), and an oxygen concentration of the liner 310 may be different from an oxygen concentration of the conductive layer 320. As an example, the oxygen concentration of the liner 310 may be higher than the oxygen concentration of the conductive layer 320.

In some implementations, the liner 310 and the conductive layer 320 further contain chlorine (Cl), and a chlorine concentration of the liner 310 may be different from a chlorine concentration of the conductive layer 320. The chlorine concentration of the conductive layer 320 may be higher than the chlorine concentration of the liner 310.

A width W3 of a bottom surface of the base portion 311 of the liner 310 may be larger than a width W2 of a bottom surface of the lower portion 321 of the conductive layer 320. The width W3 of the bottom surface of the base portion 311 of the liner 310 may be smaller than a width W4 of the interface BO between the lower and upper portions 321 and 322 of the conductive layer 320. A width W1 of the sidewall portion 312 of the liner 310 may decrease as a vertical level increases. The width W1 of the sidewall portion 312 of the liner 310 may decrease as a distance to the upper portion 322 of the conductive layer 320 decreases.

The inner sidewall S1 of the sidewall portion 312 of the liner 310 may be inclined at a first angle A1 to the top surface of the base portion 311. The outer sidewall S2 of the sidewall portion 312 of the liner 310 may be inclined at a second angle A2 to the bottom surface of the base portion 311. The sidewall S3 of the upper portion 322 of the conductive layer 320 may be inclined at a third angle A3 to the interface BO between the lower and upper portions 321 and 322 of the conductive layer 320. The first, second, and third angles A1, A2, and A3 may be obtuse angles. The second angle A2 may be smaller than the first angle A1. The first angle A1 may be equal to the third angle A3. Alternatively, the third angle A3 may be smaller than the first angle A1, and the third angle A3 may be equal to the second angle A2.

By using the liner 310 on the mold layer 210, it may be possible to stably form the conductive layer 320 on the liner 310. Since the conductive layer 320 is stably formed on the liner 310, a mean grain size of the conductive layer 320 may be increased, and in this case, an electric resistance of the semiconductor device 100 may be lowered. Grain size refers to a volume of the conductive layer 320 of a single crystal type, e.g., an area with crystal unit cells of the same symmetry. Having a larger grain size means that the structure of the conductive layer 320 is consistent, which can improve performance. Since the conductive layer 320 is stably formed on the liner 310, a seam may not be formed in the conductive layer 320, and this may make it possible to prevent melting and residue issues from occurring in a subsequent chemical mechanical polishing (CMP) process. As a result, electrical and reliability characteristics of the semiconductor device 100 may be improved.

FIGS. 2A, 2B, 2C, 2D, and 2E are sectional views illustrating an example of a method of fabricating the semiconductor device 100 according to FIGS. 1A and 1B.

Referring to FIG. 2A, the trench TR may be formed by partially removing the mold layer 210 through an etching process.

Referring to FIG. 2B, a preliminary liner p1 may be formed to cover the trench TR. The preliminary liner p1 may include at least one of conductive materials. As an example, the preliminary liner p1 may be formed of or include at least one of Mo, W, TiN, TaN, MoN, WN, TiSiN, TaSiN, MoSiN, or WSiN. In some implementations, the preliminary liner p1 may be formed through an atomic layer deposition (ALD) process or a chemical vapor deposition (CVD) process. As an example, the preliminary liner p1 may be formed through an ALD or CVD process using MoO₂Cl₂ as a precursor. The preliminary liner p1 may be formed to have a thickness of 1 nm to 3 nm. A first opening 510 may be formed on the preliminary liner p1. A portion of the trench TR, which is not filled with the preliminary liner p1, may be defined as the first opening 510.

Referring to FIG. 2C, a first sacrificial layer p2 may be formed in the first opening 510 to cover the preliminary liner p1. The first sacrificial layer p2 may be formed through an ALD or CVD process. As an example, the preliminary liner p1 may be formed through an ALD or CVD process using MoCl₅ as a precursor. A preliminary seam kl, which is an empty space, may be formed in the first sacrificial layer p2. The preliminary seam kl may be surrounded by the first sacrificial layer p2.

Referring to FIG. 2D, the first sacrificial layer p2 may be partially removed through an etching process. As a result of the partial removal of the first sacrificial layer p2, a second sacrificial layer p3 and a second opening 520 may be formed. A portion of the first sacrificial layer p2, which is located on the preliminary seam kl, may be removed by the etching process, and in this case, a remaining portion of the first sacrificial layer p2, which is left after the etching process, may be defined as the second sacrificial layer p3. Since the portion of the first sacrificial layer p2 is removed, the preliminary seam kl may be exposed to the outside. The second opening 520 may be defined to include the preliminary seam kl as well as an empty space, which is formed by partially removing the first sacrificial layer p2.

Referring to FIG. 2E, the preliminary liner p1 and the second sacrificial layer p3 may be partially removed through an etching process. As a result of the partial removal of the preliminary liner p1 and the second sacrificial layer p3, a liner 310, a preliminary conductive layer p4, and a third opening 530 may be formed. The third opening 530 may be formed to expose the mold layer 210, the liner 310, and the preliminary conductive layer p4.

Referring to FIG. 1A, the conductive layer 320 may be formed on the mold layer 210 and the liner 310 to fill the third opening 530. In some implementations, the conductive layer 320 may be formed through an ALD or CVD process. As an example, the conductive layer 320 may be formed through an ALD or CVD process using MoCl₅ as a precursor. The conductive layer 320 may be included in the preliminary conductive layer p4.

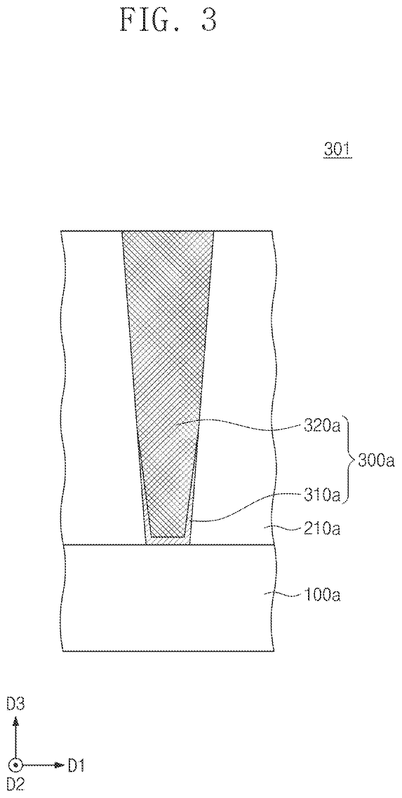

FIG. 3 is a sectional view illustrating a semiconductor device 301.

Referring to FIG. 3, the semiconductor device 301 includes a conductive structure 300a, which includes a liner 310a and a conductive layer 320a on the liner 310a, and a mold layer 210a, which is provided to enclose the conductive structure 300a.

The semiconductor device 301 may further include a substrate 100a. The mold layer 210a and the conductive structure 300a may be provided on the substrate 100a. A top surface of the substrate 100a may be in contact with a bottom surface of the liner 310a of the conductive structure 300a.

In some implementations, the substrate 100a is a semiconductor substrate. As an example, the substrate 100a may be formed of or include silicon, germanium, silicon-germanium, GaP, or GaAs. In some implementations, the substrate 100a is a silicon-on-insulator (SOI) substrate or a germanium-on-insulator (GOI) substrate.

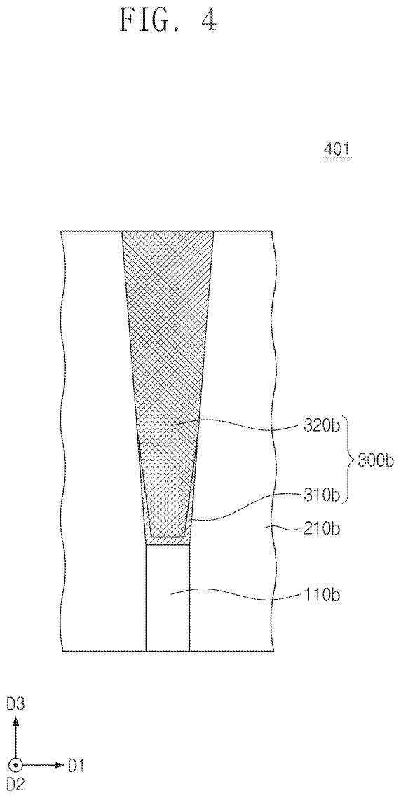

FIG. 4 is a sectional view illustrating a semiconductor device 401.

Referring to FIG. 4, a semiconductor device 401 includes a conductive structure 300b, which includes a liner 310b and a conductive layer 320b on the liner 310b, and a mold layer 210b, which is provided to enclose the conductive structure 300b.

The semiconductor device 401 may further include a material layer 110b. The material layer 110b may be enclosed by the mold layer 210b. The conductive structure 300b may be provided on the material layer 110b. A top surface of the material layer 110b may be in contact with a bottom surface of the liner 310b of the conductive structure 300b. A width of the top surface of the material layer 110b may be equal to a width of a bottom surface of the conductive structure 300b.

The mold layer 210b may include at least one of insulating materials. As an example, the mold layer 210b may be formed of or include silicon oxide (SiO₂). The material layer 110b may be formed of or include silicon (Si).

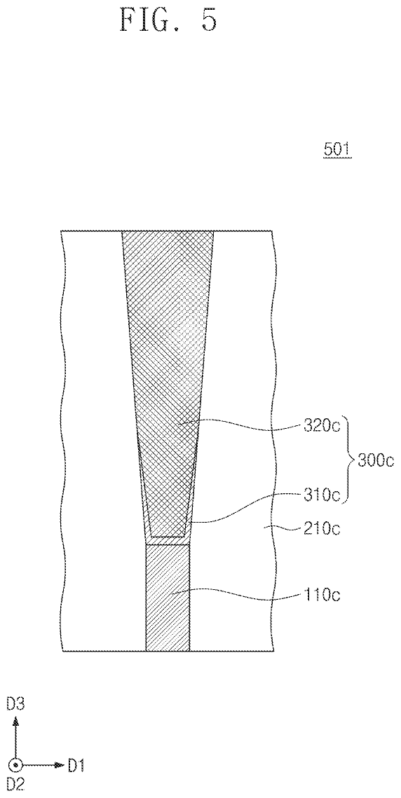

FIG. 5 is a sectional view illustrating a semiconductor device 501.

Referring to FIG. 5, the semiconductor device 501 includes a conductive structure 300c, which includes a liner 310c and a conductive layer 320c on the liner 310c, and a mold layer 210c, which is provided to enclose the conductive structure 300c.

The semiconductor device 501 may further include a material layer 110c. The material layer 110c may be enclosed by the mold layer 210c. The conductive structure 300c may be provided on the material layer 110c. A top surface of the material layer 110c may be in contact with a bottom surface of the liner 310c of the conductive structure 300c. A width of the top surface of the material layer 110c may be equal to a width of a bottom surface of the conductive structure 300c.

The mold layer 210c may include at least one of insulating materials. In some implementations, the mold layer 210c is formed of or include silicon oxide (SiO₂). The material layer 110c may include a conductive material. As an example, the material layer 110c may be formed of or include at least one of metallic materials.

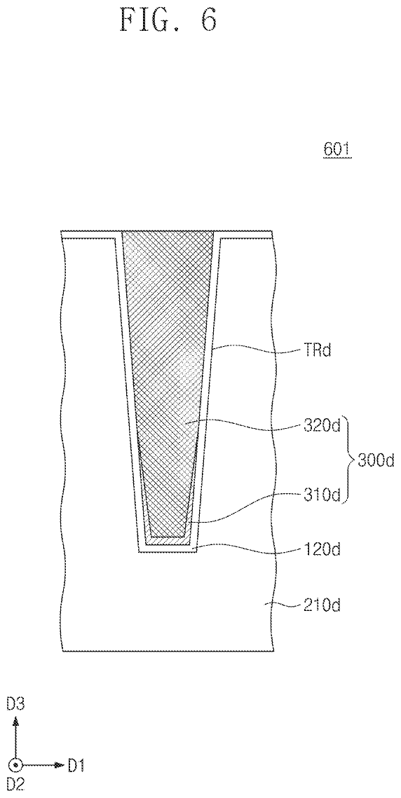

FIG. 6 is a sectional view illustrating a semiconductor device 601.

Referring to FIG. 6, the semiconductor device 601 includes a conductive structure 300d, which includes a liner 310d and a conductive layer 320d on the liner 310d, and a mold layer 210d.

The semiconductor device 601 may further include an insulating layer 120d, which is interposed between the mold layer 210d and the conductive structure 300d. A trench TRd may be defined by the mold layer 210d. The insulating layer 120d may be provided on the mold layer 210d and the trench TRd. The conductive structure 300d may be provided on the insulating layer 120d. The conductive structure 300d may be spaced apart from the mold layer 210d by the insulating layer 120d.

The insulating layer 120d and the mold layer 210d may include at least one of insulating materials. The insulating layer 120d and the mold layer 210d may be formed of or include at least one of nitride materials or oxide materials. As an example, the insulating layer 120d and the mold layer 210d may be formed of or include SiN and SiO₂, respectively.

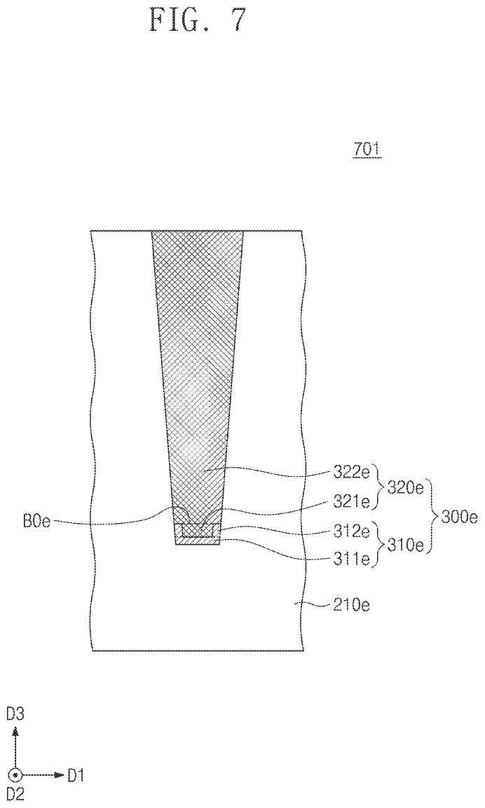

FIG. 7 is a sectional view illustrating a semiconductor device 701.

Referring to FIG. 7, the semiconductor device 701 includes a conductive structure 300e, which includes a liner 310e and a conductive layer 320e on the liner 310e, and a mold layer 210e, which is provided to enclose the conductive structure 300e.

The liner 310e may include a base portion 311e and a sidewall portion 312e on the base portion 311e. The conductive layer 320e may include a lower portion 321e and an upper portion 322e.

The sidewall portion 312e of the liner 310e may include an inner sidewall and an outer sidewall. The inner sidewall of the sidewall portion 312e may be in contact with the lower portion 321e of the conductive layer 320e. The outer sidewall of the sidewall portion 312e may be in contact with the mold layer 210e. The inner and outer sidewalls of the sidewall portion 312e may be spaced apart from each other.

The lower portion 321e of the conductive layer 320e may be disposed on the base portion 311e of the liner 310e. The lower portion 321e of the conductive layer 320e may be enclosed by the liner 310e. The upper portion 322e of the conductive layer 320e may be disposed on the sidewall portion 312e of the liner 310e and the lower portion 321e of the conductive layer 320e.

A level of a top surface of the sidewall portion 312e of the liner 310e may be equal to a level of a bottom surface of the upper portion 322e of the conductive layer 320e. The level of the top surface of the sidewall portion 312e of the liner 310e may be equal to a level of an interface BOe between the lower and upper portions 321e and 322e of the conductive layer 320e.

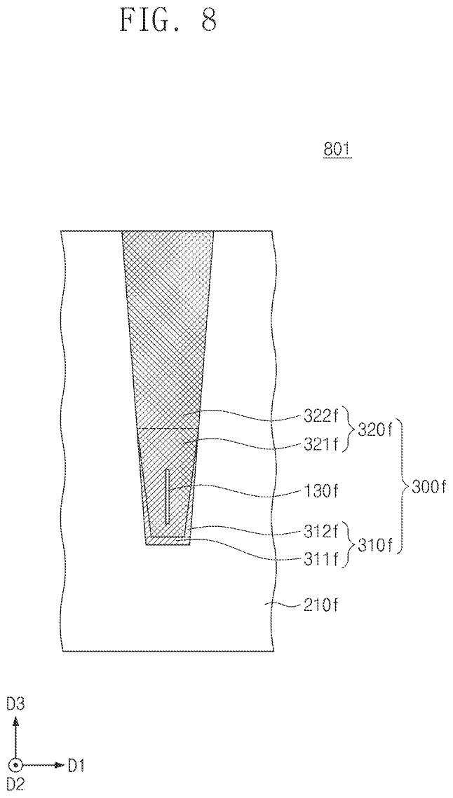

FIG. 8 is a sectional view illustrating a semiconductor device 801.

Referring to FIG. 8, the semiconductor device 801 includes a conductive structure 300f, which includes a liner 310f and a conductive layer 320f on the liner 310f, and a mold layer 210f, which is provided to enclose the conductive structure 300f.

The liner 310f may include a base portion 311f and a sidewall portion 312f on the base portion 311f. The conductive layer 320f may include a lower portion 321f and an upper portion 322f.

The conductive structure 300f may include a seam 130f, which is formed in the lower portion 321f of the conductive layer 320f. A width of the seam 130f in the first direction D1 may be smaller than a width of a bottom surface of the lower portion 321f of the conductive layer 320f in the first direction D1. A width of the seam 130f in the third direction D3 may be smaller than a width of the lower portion 321f of the conductive layer 320f in the third direction D3. The seam 130f may be spaced apart from the upper portion 322f of the conductive layer 320f, the liner 310f, and the mold layer 210f by the lower portion 321f of the conductive layer 320f. The uppermost portion of the seam 130f may be located at a level lower than the uppermost portion of the sidewall portion 312f of the liner 310f in the third direction D3. The lowermost portion of the seam 130f may be located at a level higher than a top surface of the base portion 311f of the liner 310f in the third direction D3.

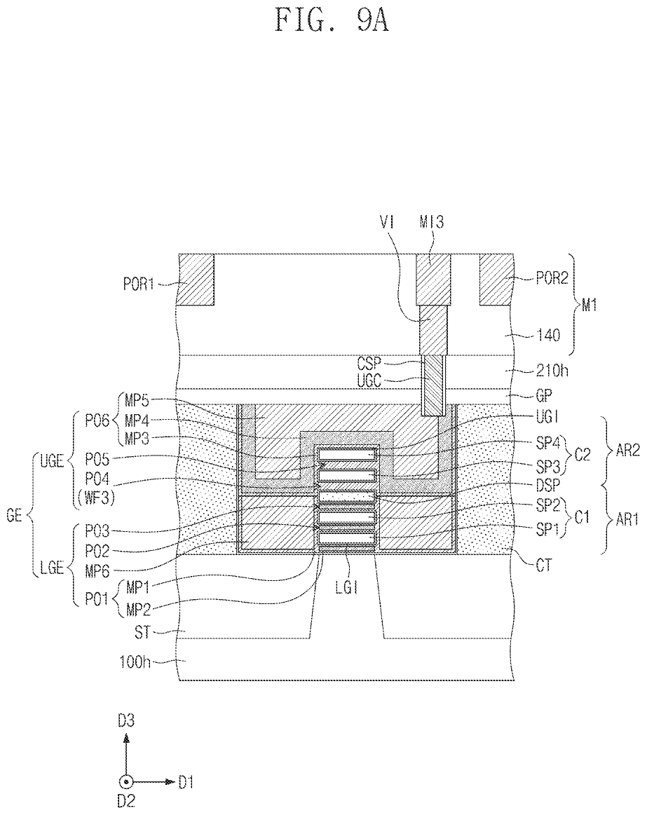

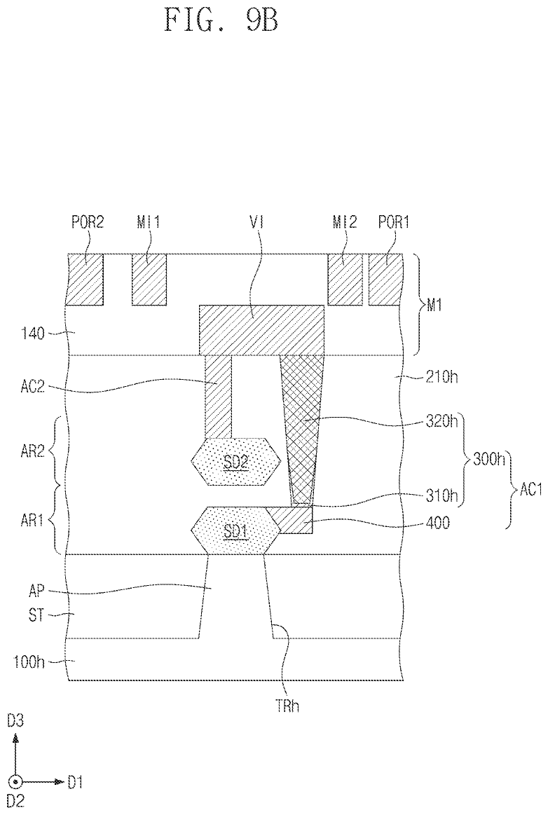

FIGS. 9A and 9B are sectional views illustrating a semiconductor device 901.

Referring to FIGS. 9A and 9B, logic transistors constituting a logic circuit are disposed on a substrate 100h. The substrate 100h may be a semiconductor substrate that is formed of or includes silicon, germanium, silicon-germanium, a compound semiconductor material, or the like. In some implementations, the substrate 100h is a silicon wafer.

A logic cell may include a first active region AR1 and a second active region AR2, which are sequentially stacked on the substrate 100h. One of the first and second active regions AR1 and AR2 may be a PMOSFET region, and the other of the first and second active regions AR1 and AR2 may be an NMOSFET region. The first active region AR1 may be provided as a bottom tier of the FEOL layer, and the second active region AR2 may be provided as a top tier of the FEOL layer. The PMOS- and NMOS-FETs of the first and second active regions AR1 and AR2 may be vertically stacked to form a three-dimensional stack transistor. In this example, the first active region AR1 may be an NMOSFET region, and the second active region AR2 may be a PMOSFET region. When viewed in a plan view, the first and second active regions AR1 and AR2 may be located between a first power line POR1 and second power line POR2.

An active pattern AP may be defined by a trench TRh, which is formed in an upper portion of the substrate 100h. The active pattern AP may be a vertically-protruding portion of the substrate 100h. When viewed in a plan view, the active pattern AP may have a bar shape extending in a second direction D2. The first and second active regions AR1 and AR2 may be sequentially stacked on the active pattern AP.

A device isolation layer ST may be provided to fill the trench TRh. The device isolation layer ST may include a silicon oxide layer. A top surface of the device isolation layer ST may be coplanar with or lower than a top surface of the active pattern AP. The device isolation layer ST may not cover lower and upper channel patterns CH1 and CH2, which will be described below.

The first active region AR1, which includes lower channel patterns CH1 and lower source/drain patterns SD1, may be provided on the active pattern AP. Each of the lower channel patterns CH1 may be interposed between a pair of the lower source/drain patterns SD1. The lower channel pattern CH1 may connect the pair of the lower source/drain patterns SD1 to each other. In the implementations illustrated herein, the phrase source/drain pattern may be understood to mean a source terminal region or a drain terminal region of a transistor.

The lower channel pattern CH1 may include a first semiconductor pattern SP1 and a second semiconductor pattern SP2, which are sequentially stacked. The first and second semiconductor patterns SP1 and SP2 may be spaced apart from each other in a vertical direction (i.e., the third direction D3). Each of the first and second semiconductor patterns SP1 and SP2 may be formed of or include at least one of silicon (Si), germanium (Ge), or silicon germanium (SiGe). In some implementations, each of the first and second semiconductor patterns SP1 and SP2 are formed of or include crystalline silicon.

The lower source/drain patterns SD1 may be provided on the top surface of the active pattern AP. Each of the lower source/drain patterns SD1 may be an epitaxial pattern, which is formed by a selective epitaxial growth (SEG) process. As an example, a top surface of the lower source/drain pattern SD1 may be higher than a top surface of the second semiconductor pattern SP2 of the lower channel pattern CH1.

The lower source/drain patterns SD1 may be doped to have a first conductivity type. The first conductivity type may be an n- or p-type. In this example, the first conductivity type is an n-type. The lower source/drain patterns SD1 may be formed of or include at least one of silicon (Si) and/or silicon germanium (SiGe).

A mold layer 210h may be provided on the device isolation layer ST. The mold layer 210h may cover the lower source/drain patterns SD1 as well as upper source/drain patterns SD2 and first and second active contacts AC1 and AC2 to be described below.

The second active region AR2 may include upper channel patterns CH2 and upper source/drain patterns SD2. The upper channel patterns CH2 may be vertically overlapped with the lower channel patterns CH1, respectively. The upper source/drain patterns SD2 may be vertically overlapped with the lower source/drain patterns SD1, respectively. Each of the upper channel patterns CH2 may be interposed between a pair of the upper source/drain patterns SD2. The upper channel pattern CH2 may connect the pair of the upper source/drain patterns SD2 to each other.

The upper channel pattern CH2 may include a third semiconductor pattern SP3 and a fourth semiconductor pattern SP4, which are sequentially stacked. The third and fourth semiconductor patterns SP3 and SP4 may be spaced apart from each other in the third direction D3. The third and fourth semiconductor patterns SP3 and SP4 of the upper channel pattern CH2 may be formed of or include the same semiconductor materials as the first and second semiconductor patterns SP1 and SP2 of the lower channel pattern CH1 described above.

At least one dummy channel pattern DSP may be interposed between the lower channel pattern CH1 and the upper channel pattern CH2 thereon. The dummy channel pattern DSP may be spaced apart from the lower source/drain patterns SD1. The dummy channel pattern DSP may be spaced apart from the upper source/drain patterns SD2. In other words, the dummy channel pattern DSP may not be connected to any source/drain pattern. The dummy channel pattern DSP may be formed of or include at least one of semiconductor materials (e.g., silicon (Si), germanium (Ge), or silicon germanium (SiGe)) or insulating materials (e.g., silicon oxide or silicon nitride).

Each of the upper source/drain patterns SD2 may be an epitaxial pattern, which is formed by a selective epitaxial growth (SEG) process. In some implementations, a top surface of the upper source/drain pattern SD2 is higher than a top surface of the fourth semiconductor pattern SP4 of the upper channel pattern CH2.

The upper source/drain patterns SD2 may be doped to have a second conductivity type. The second conductivity type may be different from the first conductivity type of the lower source/drain pattern SD1. For example, the second conductivity type may be a p-type. The upper source/drain patterns SD2 may be formed of or include silicon germanium (SiGe) and/or silicon (Si).

A gate electrode GE may be provided on the lower and upper channel patterns CH1 and CH2, which are sequentially stacked. When viewed in a plan view, the gate electrode GE may have a bar shape extending in the first direction D1. In some implementations, a plurality of gate electrodes GE are provided on the substrate 100h and may be arranged at a first pitch in the second direction D2. Each of the gate electrodes GE may be vertically overlapped with the lower and upper channel patterns CH1 and CH2 which are stacked.

The gate electrode GE may be extended from the top surface of the device isolation layer ST (or the top surface of the active pattern AP) to a gate capping pattern GP in a vertical direction (i.e., the third direction D3). The gate electrode GE may be extended from the lower channel pattern CH1 of the first active region AR1 to the upper channel pattern CH2 of the second active region AR2 in the third direction D3. The gate electrode GE may be extended from the lowermost semiconductor pattern (e.g., the first semiconductor pattern SP1) to the uppermost semiconductor pattern (e.g., the fourth semiconductor pattern SP4) in the third direction D3.

The gate electrode GE may be provided on a top surface, a bottom surface, and opposite side surfaces of each of first to fourth semiconductor patterns SP1 to SP4. That is, the transistor according to the present embodiment may include a three-dimensional field effect transistor (e.g., MBCFET or GAAFET) in which the gate electrode GE is provided to three-dimensionally surround the channel pattern.

The gate electrode GE may include a lower gate electrode LGE, which is provided in the bottom tier of the FEOL layer (i.e., the first active region AR1), and an upper gate electrode UGE, which is provided in the top tier of the FEOL layer (i.e., the second active region AR2). The lower and upper gate electrodes LGE and UGE may be vertically overlapped with each other. The lower and upper gate electrodes LGE and UGE of the gate electrode GE may be connected to each other. That is, the gate electrode GE may be a common gate electrode, in which the lower gate electrode LGE of the first active region AR1 is connected to the upper gate electrode UGE of the second active region AR2.

The lower gate electrode LGE of the gate electrode GE may include a first portion PO1 interposed between the active pattern AP and the first semiconductor pattern SP1, a second portion PO2 interposed between the first semiconductor pattern SP1 and the second semiconductor pattern SP2, and a third portion PO3 interposed between the second semiconductor pattern SP2 and the dummy channel pattern DSP.

The upper gate electrode UGE of the gate electrode GE may include a fourth portion PO4 interposed between the dummy channel pattern DSP and the third semiconductor pattern SP3, a fifth portion PO5 interposed between the third semiconductor pattern SP3 and the fourth semiconductor pattern SP4, and a sixth portion PO6 on a fourth semiconductor pattern SP4.

The gate capping pattern GP may be provided on the top surface of the gate electrode GE. The gate capping pattern GP may be extended along the gate electrode GE or in the first direction D1. For example, the gate capping pattern GP may be formed of or include at least one of SiON, SiCN, SiCON, or SiN.

A gate insulating layer UGI or LGI may be interposed between the gate electrode GE and the first to fourth semiconductor patterns SP1 to SP4. More specifically, a lower gate insulating layer LGI may be interposed between the lower gate electrode LGE and the first and second semiconductor patterns SP1 and SP2. An upper gate insulating layer UGI may be interposed between the upper gate electrode UGE and the third and fourth semiconductor patterns SP3 and SP4.

Each of the lower and upper gate insulating layers UGI and LGI may include a silicon oxide layer, a silicon oxynitride layer, and/or a high-k dielectric layer. In some implementations, each of the lower and upper gate insulating layers UGI and LGI includes a silicon oxide layer, which is provided to directly cover a surface of at least one of the first to fourth semiconductor pattern SP1 to SP4, and a high-k dielectric layer, which is provided on the silicon oxide layer. In other words, each of the lower and upper gate insulating layers UGI and LGI may have a multi-layered structure.

The lower gate electrode LGE of the gate electrode GE may include a first metal pattern MP1 on the first and second semiconductor patterns SP1 and SP2 and a second metal pattern MP2 on the first metal pattern MP1.

The first metal pattern MP1 may include at least one metallic element, which is selected from the group consisting of titanium (Ti), tantalum (Ta), aluminum (Al), tungsten (W), and molybdenum (Mo), and nitrogen (N). For example, the first metal pattern MP1 may be formed of or include at least one of titanium nitride (TiN), tantalum nitride (TaN), titanium oxynitride (TiON), titanium silicon nitride (TiSiN), titanium aluminum nitride (TiAlN), tungsten carbon nitride (WCN), or molybdenum nitride (MoN).

The second metal pattern MP2 may be formed of or include at least one of metal carbides. The second metal pattern MP2 may be formed of or include at least one of metal carbides that are doped with silicon and/or aluminum and contain silicon and/or aluminum. As an example, the second metal pattern MP2 may be formed of or include aluminum-doped titanium carbide (TiAlC), aluminum-doped tantalum carbide (TaAlC), aluminum-doped vanadium carbide (VAlC), silicon-doped titanium carbide (TiSiC), or silicon-doped tantalum carbide (TaSiC). As another example, the second metal pattern MP2 may be formed of or include titanium carbide doped with aluminum and silicon (TiAlSiC) or tantalum carbide doped with aluminum and silicon (TaAlSiC). As another example, the second metal pattern MP2 may be formed of or include aluminum-doped titanium (TiAl). As another example, the second metal pattern MP2 may be formed of or include a metal nitride doped with silicon and/or aluminum (e.g., aluminum-doped titanium nitride (TiAlN)).

Each of the first, second and third portions PO1, PO2, and PO3 of the lower gate electrode LGE may be composed of the second metal pattern MP2 and the first metal pattern MP1 enclosing the second metal pattern MP2. In some implementations, a thickness of the second metal pattern MP2 is larger than a thickness of the first metal pattern MP1.

The lower gate electrode LGE may further include a sixth metal pattern MP6, which is provided as a remaining portion of the lower gate electrode LGE except the first, second and third portions PO1, PO2 and PO3, in addition to the first and second metal patterns MP1 and MP2. The sixth metal pattern MP6 may have a lower resistance than the first and second metal patterns MP1 and MP2. As an example, the sixth metal pattern MP6 may be formed of or include at least one of low resistance metallic materials (e.g., tungsten (W), ruthenium (Ru), aluminum (Al), titanium (Ti), and tantalum (Ta)).

A top surface of the sixth metal pattern MP6 of the gate electrode GE may be in contact with a bottom surface of the upper gate electrode UGE. The top surface of the sixth metal pattern MP6 may be located at a level between the top and bottom surfaces of the dummy channel pattern DSP.

The upper gate electrode UGE of the gate electrode GE may include a third metal pattern MP3 on the third and fourth semiconductor patterns SP3 and SP4. The third metal pattern MP3 may be provided to enclose the third and fourth semiconductor patterns SP3 and SP4. The upper gate electrode UGE may further include a fourth metal pattern MP4 and a fifth metal pattern MP5 on the third metal pattern MP3.

The third metal pattern MP3 may be formed of or include at least one of metal nitrides. The third metal pattern MP3 may be formed of or include a metal nitride material, which is the same as or different from that in the first metal pattern MP1.

The fourth metal pattern MP4 may be formed of or include at least one of metal carbides that are doped with silicon and/or aluminum and contain silicon and/or aluminum. The fourth metal pattern MP4 may be formed of or include a material, which is the same as or different from the second metal pattern MP2.

The fourth and fifth portions PO4 and PO5 of the upper gate electrode UGE may be composed of the third metal pattern MP3. The sixth portion PO6 of the upper gate electrode UGE may include the third metal pattern MP3, the fourth metal pattern MP4, and the fifth metal pattern MP5, which are sequentially stacked.

The fifth metal pattern MP5 may be formed of or include the same metal nitride material as the third metal pattern MP3. In some implementations, the fifth metal pattern MP5 are formed of or include at least one of low resistance metallic materials. For example, the fifth metal pattern MP5 may be formed of or include the same metallic material as the sixth metal pattern MP6.

A gate cutting pattern CT may be provided to penetrate the gate electrode GE. The gate electrode GE may be separated from another gate electrode, which is adjacent thereto in the first direction D1, by the gate cutting pattern CT. For example, a pair of gate cutting patterns CT may be respectively provided at both sides of the gate electrode GE. The gate cutting patterns CT may be formed of or include at least one of insulating materials (e.g., silicon oxide and silicon nitride).

A gate contact UGC may be provided to penetrate an interlayer insulating layer 140 and the gate capping pattern GP and may be electrically connected to the gate electrode GE.

Each of the gate contacts UGC may be formed of or include at least one of metallic materials (e.g., copper (Cu), aluminum (Al), ruthenium (Ru), cobalt (Co), tungsten (W), and molybdenum (Mo)). Each of the gate contacts UGC may have a pillar shape extending in the third direction D3. A contact spacer CSP may be provided to enclose an outer side surface of each of the gate contacts UGC.

The first active contact AC1 may be provided on at least one lower source/drain pattern SD1. The first active contact AC1 may include a conductive structure 300h and a horizontal structure 400. The conductive structure 300h and the horizontal structure 400 may be connected to each other to form a single first active contact AC1. In some implementations, the first active contact AC1 is formed of or includes at least one of doped semiconductor materials and/or metallic materials. As an example, the first active contact AC1 may be formed of or include molybdenum (Mo). The conductive structure 300h may be vertically extended to penetrate at least a portion of the mold layer 210h. The conductive structure 300h of the first active contact AC1 may be horizontally offset from the stacked lower and upper source/drain patterns SD1 and SD2. The conductive structure 300h may be provided in the bottom tier of the FEOL layer. The horizontal structure 400 may be extended in the first direction D1 and may overlap with the lower source/drain pattern SD1 along a horizontal direction. The conductive structure 300h may be provided on the horizontal structure 400. The conductive structure 300h may be coupled to the lower source/drain pattern SD1 through the horizontal structure 400.

The conductive structure 300h may include a liner 310h and a conductive layer 320h on the liner 310h. The liner 310h may be provided on the horizontal structure 400. A bottom surface of the liner 310h may be in contact with a top surface of the horizontal structure 400. A via VI, which will be described below, may be provided on the conductive layer 320h. A top surface of the conductive layer 320h may be in contact with a bottom surface of the via VI.

The second active contact AC2 may be provided on at least one upper source/drain pattern SD2. The second active contact AC2 may be spaced apart from the first active contact AC1 in the first direction D1. The second active contact AC2 may be vertically overlapped with the upper source/drain pattern SD2.

The second active contact AC2 may be provided in the top tier of the FEOL layer. The second active contact AC2 may have a vertically extending pillar shape. The second active contact AC2 may be directly coupled to the upper source/drain pattern SD2. In some implementations, the second active contact AC2 is formed of or include the same material as the first active contact AC1.

The interlayer insulating layer 140 may be provided on the mold layer 210h. A first metal layer M1 may be provided in the interlayer insulating layer 140. The first metal layer M1 may include a first power line POR1, a second power line POR2, and first to third interconnection lines MI1 to MI3.

A drain voltage (VDD) may be applied to one of the first and second power lines POR1 and POR2, and a source voltage (VSS) may be applied to the other of the first and second power lines POR1 and POR2. In some implementations, the source voltage (VSS) is applied to the first power line POR1, and the drain voltage (VDD) may be applied to the second power line POR2.

The first to third interconnection lines MI1 to MI3 may be disposed between the first power line POR1 and the second power line POR2. The first to third interconnection lines MI1 to MI3 may be line- or bar-shaped patterns extending in the second direction D2. The first and second power lines POR1 and POR2 and the first to third interconnection lines MI1 to MI3 may be formed of or include at least one metallic material that is selected from the group consisting of copper (Cu), aluminum (Al), ruthenium (Ru), cobalt (Co), tungsten (W), and molybdenum (Mo).

The first metal layer M1 may further include vias VI, which are provided in a lower portion of the interlayer insulating layer 140. A first one of the vias VI may be used to connect the active contact AC1 or AC2 to the power line POR1 or POR2. A second one of the vias VI may be used to connect the second active contacts AC2, which are adjacent to each other. A third one of the vias VI may be used to connect the gate contact UGC to at least one of the interconnection lines MI1 to MI3.

Additional metal layers (e.g., M2, M3, M4, and so forth) may be stacked on the first metal layer M1. The first metal layer M1 and the additional metal layers (e.g., M2, M3, M4, and so forth) thereon may constitute a back-end-of-line (BEOL) layer of the semiconductor device. The additional metal layers (e.g., M2, M3, M4, and so forth) on the first metal layer M1 may include routing lines, which are used to connect the logic cells to each other.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a mold layer defining a trench; and
a conductive structure disposed on the trench, wherein the conductive structure comprises
a conductive layer comprising upper and lower portions and a liner comprising a base portion and a sidewall portion on the base portion,
wherein the upper portion of the conductive layer is disposed at a level higher than the sidewall portion of the liner,
wherein the sidewall portion of the liner is interposed between the lower portion of the conductive layer and the mold layer,
a top surface of the base portion of the liner is in contact with a bottom surface of the lower portion of the conductive layer, and
a width of the sidewall portion of the liner decreases as a vertical level of the liner increases.

2. The semiconductor device of claim 1, wherein the conductive layer and the liner comprise molybdenum (Mo), and the liner further comprises oxygen (O).

3. The semiconductor device of claim 1, wherein the conductive layer comprises molybdenum (Mo), and the liner comprises titanium nitride (TiN).

4. The semiconductor device of claim 1, wherein the conductive layer and the liner comprise chlorine (Cl), and a chlorine concentration of the conductive layer is higher than a chlorine concentration of the liner.

5. The semiconductor device of claim 1, further comprising a substrate containing silicon (Si), wherein the mold layer and the conductive structure are provided on the substrate.

6. The semiconductor device of claim 1, further comprising a material layer enclosed by the mold layer,
wherein the conductive structure is provided on the material layer, and
a width of a top surface of the material layer is equal to a width of a bottom surface of the conductive structure.

7. The semiconductor device of claim 6, wherein the material layer comprises a metallic material.

8. The semiconductor device of claim 6, wherein the material layer comprises silicon (Si).

9. The semiconductor device of claim 1, wherein a width of a bottom surface of the conductive structure is equal to or less than 20 nm.

10. The semiconductor device of claim 1, wherein a height of the conductive structure ranges from 100 nm to 1000 nm.

11. A semiconductor device, comprising:
a mold layer defining a trench; and
a conductive structure disposed on the trench, wherein the conductive structure comprises
a conductive layer comprising upper and lower portions and a liner comprising a base portion and a sidewall portion on the base portion,
wherein the sidewall portion is interposed between the lower portion of the conductive layer and the mold layer,
wherein the sidewall portion comprises an inner sidewall in contact with the lower portion of the conductive layer and an outer sidewall in contact with the mold layer, and
wherein an angle between the outer sidewall of the sidewall portion and a bottom surface of the base portion is smaller than an angle between the inner sidewall of the sidewall portion and a top surface of the base portion.

12. The semiconductor device of claim 11, wherein the conductive layer and the liner comprise molybdenum (Mo) and chlorine (Cl),
a chlorine concentration of the conductive layer is higher than a chlorine concentration of the liner, and
the liner further comprises oxygen (O).

13. The semiconductor device of claim 11, wherein the conductive structure comprises a seam formed in the lower portion of the conductive layer.

14. The semiconductor device of claim 11, further comprising an insulating layer interposed between the mold layer and the conductive structure,
wherein the conductive structure is provided on the insulating layer,
the insulating layer comprises a nitride material, and
the conductive structure is spaced apart from the mold layer by the insulating layer.

15. The semiconductor device of claim 11, wherein the conductive layer and the liner comprises molybdenum (Mo) and oxygen (O), and
an oxygen concentration of the liner is higher than an oxygen concentration of the conductive layer.

16. The semiconductor device of claim 11, wherein the mold layer comprises a nitride material.

17. The semiconductor device of claim 11, wherein the upper portion of the conductive layer comprises a sidewall in contact with the mold layer, and
an angle between the outer sidewall of the sidewall portion and the bottom surface of the base portion is equal to an angle between the sidewall and an interface of the lower and upper portions of the conductive layer.

18. A semiconductor device, comprising:
a mold layer defining a trench; and
a conductive structure disposed on the trench and comprising a conductive layer and a liner,
wherein the liner is interposed between the mold layer and the conductive layer,
wherein the conductive layer and the liner comprise molybdenum (Mo), and
wherein the liner further comprises oxygen (O).

19. The semiconductor device of claim 18, wherein the conductive layer comprises upper and lower portions,
the liner comprises a base portion and a sidewall portion on the base portion,
the lower portion of the conductive layer is disposed on the base portion of the liner,
a top surface of the sidewall portion of the liner is located at the same level as an interface of the upper and lower portions of the conductive layer, and
the upper portion of the conductive layer is disposed on the sidewall portion of the liner and the lower portion of the conductive layer.

20. The semiconductor device of claim 18, wherein the mold layer comprises an oxide material.
